(19) United States
(12) Patent Application Publication
(10) Pub. No.: US 2025/0374555 A1
(43) Pub. Date: Dec. 4, 2025

(54) RESISTIVE RANDOM ACCESS MEMORY DEVICE AND FABRICATION METHOD THEREOF

(71) Applicant: UNITED MICROELECTRONICS CORP., Hsin-Chu City (TW)

(72) Inventors: Wen-Jen Wang, Tainan City (TW); Yu-Huan Yeh, Taichung City (TW); Chuan-Fu Wang, Miaoli County (TW)

(73) Assignee: UNITED MICROELECTRONICS CORP., Hsin-Chu City (TW)

(21) Appl. No.: 18/752,807

(22) Filed: Jun. 25, 2024

(30) Foreign Application Priority Data
May 29, 2024 (TW) 113119829

(51) Int. Cl. H10B 63/00; H10N 70/00

(52) U.S. Cl. CPC H10B 63/00; H10N 70/063; H10N 70/8265

(57) ABSTRACT

A resistive random access memory device includes a first ILD layer on a substrate; a first interconnect structure in the first ILD layer; a capping layer on the first interconnect structure and the first ILD layer; an intermediate dielectric layer on the capping layer; a conductive via in the capping layer and the intermediate dielectric layer; and a resistive switching element on the conductive via. The resistive switching element includes a bottom electrode layer, a top electrode layer, and a resistive switching material layer interposed between the top electrode layer and the bottom electrode layer. A hard mask layer is disposed on the resistive switching element. A second interconnect structure is disposed on the hard mask layer and the resistive switching element. The second interconnect structure includes a lug portion that is in direct contact with an upper sidewall of the top electrode layer of the resistive switching element.

### BACKGROUND OF THE INVENTION

### 1. Field of the Invention

The present invention relates to the field of semiconductor technology, and in particular to a resistive random access memory (RRAM) device and a manufacturing method thereof.

### 2. Description of the Prior Art

Resistive random access memory (RRAM) is a memory structure including an array of RRAM cells each of which stores a bit of data using resistance values, rather than electronic charge. Particularly, each RRAM cell includes a resistive-switching material layer, the resistance of which can be adjusted to represent logic “0” or logic “1.”

In advanced technology nodes, the feature size scales down and the size of memory devices is reduced accordingly. However, the reduction of the RRAM devices is limited due to the “forming” operation. In the “forming” process, a high voltage is applied to the RRAM device to generate a conductive path in the resistive-switching material layer.

During the RRAM manufacturing process, the etching process can damage the top electrode of the resistive switching element, causing uneven surface contours on the top electrode. This unevenness affects the uniform deposition of the barrier layer in the subsequent upper interconnect structure, leading to reduced device reliability.

### SUMMARY OF THE INVENTION

It is one object of the present invention to provide an improved resistive random access memory (RRAM) device and a manufacturing method thereof to solve the deficiencies or shortcomings of the existing technology.

One aspect of the invention provides a resistive random access memory device including a substrate; a first inter-layer dielectric (ILD) layer disposed on the substrate; a first interconnect structure disposed in the first ILD layer; a capping layer disposed on the first interconnect structure and the first ILD layer; an intermediate dielectric layer disposed on the capping layer; and a conductive via disposed in the capping layer and the intermediate dielectric layer. The conductive via is electrically coupled to the first interconnect structure. A resistive switching element is disposed on the conductive via. The resistive switching element includes a bottom electrode layer, a top electrode layer, and a resistive switching material layer interposed between the top electrode layer and the bottom electrode layer. A hard mask layer is disposed on the resistive switching element. A second interconnect structure is disposed on the hard mask layer and the resistive switching element. The second interconnect structure comprises a lug portion that is in direct contact with an upper sidewall of the top electrode layer of the resistive switching element.

According to some embodiments, the resistive random access memory device further includes a sidewall spacer surrounding the resistive switching element.

According to some embodiments, the resistive random access memory device further includes a second inter-layer dielectric (ILD) layer disposed around the sidewall spacer and the second interconnect structure.

According to some embodiments, the sidewall spacer is in direct contact with the resistive switching element and the intermediate dielectric layer.

According to some embodiments, the sidewall spacer comprises a silicon nitride layer or a silicon oxide layer.

According to some embodiments, the hard mask layer comprises a silicon oxide layer or a silicon nitride layer.

According to some embodiments, the conductive via comprises a barrier layer and a tungsten layer on the barrier layer.

According to some embodiments, the barrier layer comprises titanium nitride.

According to some embodiments, the capping layer comprises a nitrogen-doped silicon carbide (NDC) layer.

According to some embodiments, the intermediate dielectric layer comprises a TEOS-based silicon oxide layer.

Another aspect of the invention provides a method for forming a resistive random access memory device. A substrate is provided. A first inter-layer dielectric (ILD) layer is formed on the substrate. A first interconnect structure is formed in the first ILD layer. A capping layer is formed on the first interconnect structure and the first ILD layer. An intermediate dielectric layer is formed on the capping layer. A conductive via is formed in the capping layer and the intermediate dielectric layer. The conductive via is electrically coupled to the first interconnect structure. A resistive switching element is formed on the conductive via. The resistive switching element comprises a bottom electrode layer, a top electrode layer, and a resistive switching material layer interposed between the top electrode layer and the bottom electrode layer. A hard mask layer is formed on the resistive switching element. A second interconnect structure is formed on the hard mask layer and the resistive switching element. The second interconnect structure comprises a lug portion that is in direct contact with an upper sidewall of the top electrode layer of the resistive switching element.

According to some embodiments, the method further includes the step of forming a sidewall spacer surrounding the resistive switching element.

According to some embodiments, the method further includes the step of forming a second inter-layer dielectric (ILD) layer around the sidewall spacer and the second interconnect structure.

According to some embodiments, the sidewall spacer is in direct contact with the resistive switching element and the intermediate dielectric layer.

According to some embodiments, the sidewall spacer comprises a silicon nitride layer or a silicon oxide layer.

According to some embodiments, the hard mask layer comprises a silicon oxide layer or a silicon nitride layer.

According to some embodiments, the conductive via comprises a barrier layer and a tungsten layer on the barrier layer.

According to some embodiments, the barrier layer comprises titanium nitride.

According to some embodiments, the capping layer comprises a nitrogen-doped silicon carbide (NDC) layer.

According to some embodiments, the intermediate dielectric layer comprises a TEOS-based silicon oxide layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 are schematic diagrams illustrating a method of manufacturing a resistive random access memory device according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

Please refer to FIG. 1 to FIG. 6, which are schematic diagrams illustrating a method of manufacturing a resistive random access memory device according to an embodiment of the present invention. As shown in FIG. 1, a substrate 100 is first provided. According to an embodiment of the present invention, the substrate 100 may be a semiconductor substrate, for example, a silicon substrate, but is not limited thereto. A first inter-layer dielectric (ILD) layer 110 is formed on the substrate 100. According to an embodiment of the present invention, for example, the first ILD layer 110 may comprise a low dielectric constant (low-k) material layer or an ultra-low dielectric constant (ULK) material layer. According to an embodiment of the present invention, the thickness of the first ILD layer 110 may be, for example, about 800-900 angstroms.

According to an embodiment of the present invention, a first interconnect structure M1 is then formed in the first ILD layer 110. According to an embodiment of the present invention, for example, the first interconnect structure M1 may be a copper damascene structure formed by a copper damascene process. According to an embodiment of the present invention, a capping layer 120 is formed on the first interconnect structure M1 and the first ILD layer 110. According to an embodiment of the present invention, for example, the capping layer 120 may include a nitrogen-doped silicon carbide (NDC) layer, but is not limited thereto. According to an embodiment of the present invention, the thickness of the capping layer 120 is about 100 angstroms, for example.

According to an embodiment of the present invention, an intermediate dielectric layer 130 is formed on the capping layer 120. According to an embodiment of the present invention, for example, the intermediate dielectric layer 130 may include a tetraethoxysilane-based (TEOS-based) silicon oxide layer, but is not limited thereto. According to an embodiment of the present invention, the thickness of the intermediate dielectric layer 130 may be, for example, approximately 100-500 angstroms.

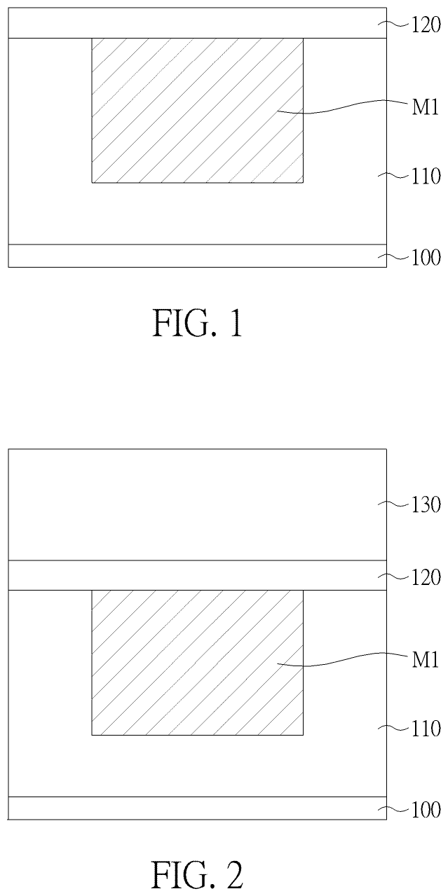

As shown in FIG. 2, a chemical vapor deposition (CVD) process is then performed to deposit an intermediate dielectric layer 130 on the capping layer 120. According to an embodiment of the present invention, the intermediate dielectric layer 130 includes, for example, a TEOS-based silicon oxide layer.

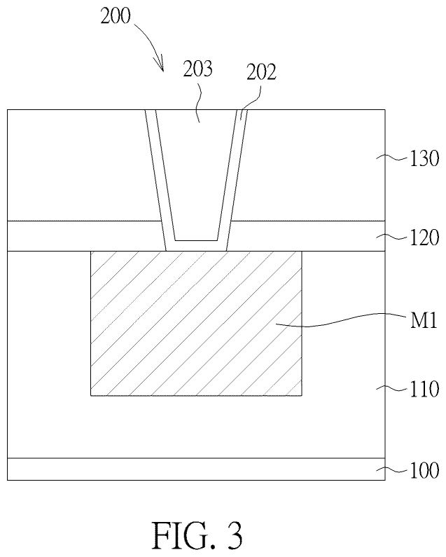

As shown in FIG. 3, a photolithography process, an etching process and a metallization process are performed to form a conductive via 200 in the intermediate dielectric layer 130 and the capping layer 120 so that the conductive via 200 is electrically connected to the underlying first interconnect structure M1. According to an embodiment of the present invention, the height of the conductive via 200 is approximately between 200-600 angstroms, for example, between 400-500 angstroms. According to an embodiment of the present invention, for example, the conductive via 200 may include a barrier layer 202 and a tungsten layer 203 located on the barrier layer 202. According to an embodiment of the present invention, the barrier layer 202 may include titanium nitride, for example, but is not limited thereto. A tungsten chemical mechanical polishing (WCMP) process may be performed to remove the excess tungsten layer 203 on the intermediate dielectric layer 130.

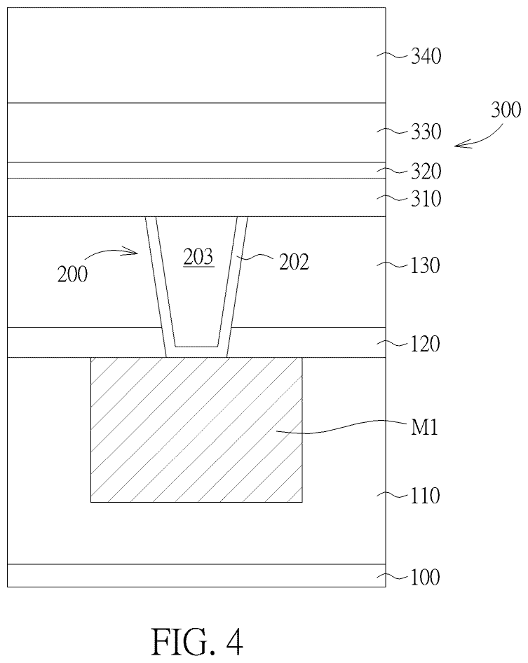

As shown in FIG. 4, a deposition process is then performed to form a film stack structure 300 on the conductive via 200 and the intermediate dielectric layer 130. According to an embodiment of the present invention, for example, the film stack structure 300 may include a bottom electrode layer 310, a resistive switching layer 320, a top electrode layer 330, and a hard mask layer 340. According to an embodiment of the present invention, for example, the bottom electrode layer 310 may include TaN, TiN, Pt, Ir, Ru or W, but is not limited thereto. The resistive switching layer 320 may include hafnium oxide, tantalum oxide, titanium, titanium oxide, or combinations thereof, but is not limited thereto. The top electrode layer 330 may include TIN, TaN, Pt, Ir, or W, but is not limited thereto. The hard mask layer 340 may include a silicon oxide layer or a silicon nitride layer, but is not limited thereto.

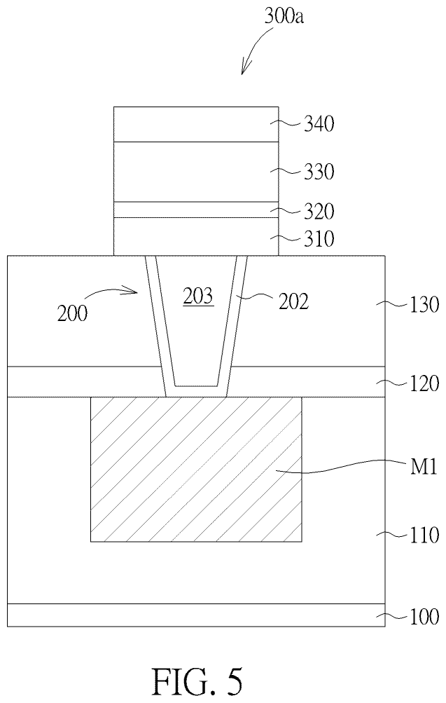

As shown in FIG. 5, a photolithography process and an etching process are then performed to pattern the film stack structure 300 into a resistive switching element 300a. At this point, the hard mask layer 340 having a predetermined thickness may remain on the top electrode layer 330. According to an embodiment of the present invention, for example, the above-mentioned predetermined thickness may range from 0-500 angstroms, but is not limited thereto.

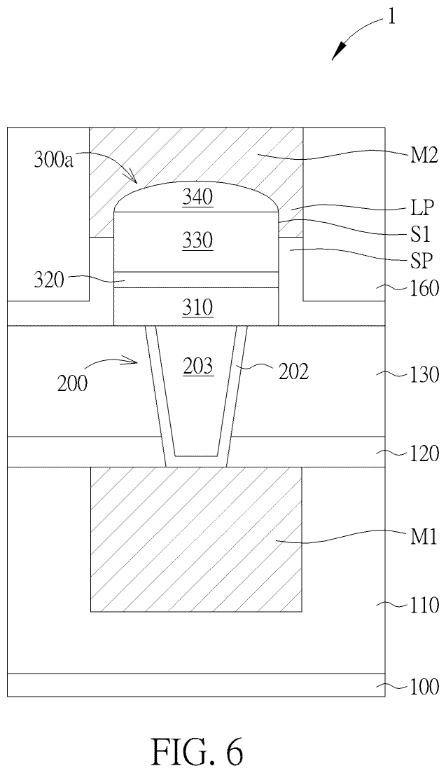

As shown in FIG. 6, a deposition process is performed to form sidewall spacer SP surrounding the resistive switching element 300a. According to an embodiment of the present invention, for example, the sidewall spacer SP may include a silicon nitride layer or a silicon oxide layer. According to an embodiment of the present invention, the sidewall spacer SP directly contacts the resistive switching element 300a and the intermediate dielectric layer 130. Next, a deposition process is performed to form a second interlayer dielectric (ILD) layer 160 on the sidewall spacer SP and the resistive switching element 300a, so that the second ILD layer 160 covers the remaining hard mask layer 340. According to an embodiment of the present invention, for example, the second ILD layer 160 may include a low dielectric constant material layer or an ultra-low dielectric constant material layer.

A photolithography process, an etching process and a metallization process are then used to form a second interconnect structure M2 on the second ILD layer 160, which is disposed on the hard mask layer 340 and the resistive switching element 300a. The second interconnect structure M2 includes a lug portion LP in direct contact with the upper sidewall S1 of the top electrode layer 330 of the resistive switching element 300a. According to an embodiment of the present invention, for example, the lug portion LP extends downward no more than half the thickness of the top electrode layer 330.

Since all (or at least most, for example, at least 80% or more of the area) of the top surface of the top electrode layer 330 of the resistive switching element 300a is covered by the remaining hard mask layer 340, the second interconnect structure M2 is only in direct contact with the upper sidewall S1 (or the upper sidewall S1 and the top corner) of the top electrode layer 330. During operation, current flows through the lug portion LP and the upper sidewall S1 of the top electrode layer 330 to complete the resistance state switching of the resistive switching element 300a.

Structurally, as shown in FIG. 6, the resistive random access memory device 1 includes: a substrate 100; a first ILD layer 110 disposed on the substrate 100; a first interconnect structure M1 disposed on the first ILD layer 110; a capping layer 120 disposed on the first interconnect structure M1 and the first ILD layer 110; an intermediate dielectric layer 130 disposed on the capping layer 120; and a conductive via 200 disposed in the capping layer 120 and the intermediate dielectric layer 130. The conductive via 200 is electrically connected to the first interconnect structure M1.

According to an embodiment of the present invention, the resistive random access memory device 1 further includes: a resistive switching element 300a disposed on the conductive via 200. The resistive switching element 300a includes a bottom electrode layer 310, a top electrode layer 330, and a resistive switching layer 320 between the top electrode layer 330 and the bottom electrode layer 310.

According to an embodiment of the present invention, the resistive random access memory device 1 further includes a hard mask layer 340 disposed on the resistive switching element 300a.

According to an embodiment of the present invention, the resistive random access memory device 1 further includes: a second interconnect structure M2 disposed on the hard mask layer 340 and the resistive switching element 300a. The second interconnect structure M2 includes a lug portion LP in direct contact with the upper sidewall S1 of the top electrode layer 330 of the resistive switching element 300a.

According to an embodiment of the present invention, the resistive random access memory device 1 further includes: sidewall spacer SP surrounding the resistive switching element 300a.

According to an embodiment of the present invention, the resistive random access memory device 1 further includes: a second ILD layer 160 disposed around the sidewall spacer SP and the second interconnect structure M2.

According to an embodiment of the present invention, the sidewall spacer SP directly contacts the resistive switching element 300a and the intermediate dielectric layer 130.

According to an embodiment of the present invention, the sidewall spacer SP includes a silicon nitride layer or a silicon oxide layer.

According to an embodiment of the present invention, the hard mask layer 340 includes a silicon oxide layer or a silicon nitride layer.

According to an embodiment of the present invention, the conductive via 200 includes a barrier layer 202 and a tungsten layer 203 located on the barrier layer 202.

According to an embodiment of the invention, barrier layer 202 includes titanium nitride.

According to an embodiment of the present invention, the capping layer 120 includes a nitrogen-doped silicon carbide layer.

According to an embodiment of the present invention, the intermediate dielectric layer 130 includes a TEOS-based silicon oxide layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A resistive random access memory device, comprising:
a substrate;
a first inter-layer dielectric (ILD) layer disposed on the substrate;
a first interconnect structure disposed in the first ILD layer;
a capping layer disposed on the first interconnect structure and the first ILD layer;
an intermediate dielectric layer disposed on the capping layer;
a conductive via disposed in the capping layer and the intermediate dielectric layer, wherein the conductive via is electrically coupled to the first interconnect structure;
a resistive switching element disposed on the conductive via, wherein the resistive switching element comprises a bottom electrode layer, a top electrode layer, and a resistive switching material layer interposed between the top electrode layer and the bottom electrode layer;
a hard mask layer disposed on the resistive switching element; and
a second interconnect structure disposed on the hard mask layer and the resistive switching element, wherein the second interconnect structure comprises a lug portion that is in direct contact with an upper sidewall of the top electrode layer of the resistive switching element.

2. The resistive random access memory device according to claim 1 further comprising:
a sidewall spacer surrounding the resistive switching element.

3. The resistive random access memory device according to claim 2 further comprising:
a second inter-layer dielectric (ILD) layer disposed around the sidewall spacer and the second interconnect structure.

4. The resistive random access memory device according to claim 2, wherein the sidewall spacer is in direct contact with the resistive switching element and the intermediate dielectric layer.

5. The resistive random access memory device according to claim 2, wherein the sidewall spacer comprises a silicon nitride layer or a silicon oxide layer.

6. The resistive random access memory device according to claim 1, wherein the hard mask layer comprises a silicon oxide layer or a silicon nitride layer.

7. The resistive random access memory device according to claim 1, wherein the conductive via comprises a barrier layer and a tungsten layer on the barrier layer.

8. The resistive random access memory device according to claim 7, wherein the barrier layer comprises titanium nitride.

9. The resistive random access memory device according to claim 1, wherein the capping layer comprises a nitrogen-doped silicon carbide (NDC) layer.

10. The resistive random access memory device according to claim 1, wherein the intermediate dielectric layer comprises a TEOS-based silicon oxide layer.

11. A method for forming a resistive random access memory device, comprising:
providing a substrate;
forming a first inter-layer dielectric (ILD) layer on the substrate;
forming a first interconnect structure in the first ILD layer;
forming a capping layer on the first interconnect structure and the first ILD layer;
forming an intermediate dielectric layer on the capping layer;
forming a conductive via in the capping layer and the intermediate dielectric layer, wherein the conductive via is electrically coupled to the first interconnect structure;
forming a resistive switching element on the conductive via, wherein the resistive switching element comprises a bottom electrode layer, a top electrode layer, and a resistive switching material layer interposed between the top electrode layer and the bottom electrode layer;
forming a hard mask layer on the resistive switching element; and
forming a second interconnect structure on the hard mask layer and the resistive switching element, wherein the second interconnect structure comprises a lug portion that is in direct contact with an upper sidewall of the top electrode layer of the resistive switching element.

12. The method according to claim 11 further comprising:
forming a sidewall spacer surrounding the resistive switching element.

13. The method according to claim 12 further comprising:
forming a second inter-layer dielectric (ILD) layer around the sidewall spacer and the second interconnect structure.

14. The method according to claim 12, wherein the sidewall spacer is in direct contact with the resistive switching element and the intermediate dielectric layer.

15. The method according to claim 12, wherein the sidewall spacer comprises a silicon nitride layer or a silicon oxide layer.

16. The method according to claim 11, wherein the hard mask layer comprises a silicon oxide layer or a silicon nitride layer.

17. The method according to claim 11, wherein the conductive via comprises a barrier layer and a tungsten layer on the barrier layer.

18. The method according to claim 17, wherein the barrier layer comprises titanium nitride.

19. The method according to claim 11, wherein the capping layer comprises a nitrogen-doped silicon carbide (NDC) layer.

20. The method according to claim 11, wherein the intermediate dielectric layer comprises a TEOS-based silicon oxide layer.
